(19) United States
(12) Patent Application Publication
(10) Pub. No.: US 2026/0114289 A1
(43) Pub. Date: Apr. 23, 2026

(54) FAN-OUT CHIP PACKAGING STRUCTURE BASED ON SHIELDED METAL CARRIER PLATE AND METHOD FOR MANUFACTURING SAME

(71) Applicant: SHANGHAI INSTITUTE OF MICROSYSTEM AND INFORMATION TECHNOLOGY, CHINESE ACADEMY OF SCIENCES, Shanghai (CN)

(72) Inventor: XIAO Kelaiti, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 19/116,391

(22) PCT Filed: Mar. 20, 2024
(86) PCT No.: PCT/CN2024/082753

§ 371 Date: Mar. 28, 2025

(30) Foreign Application Priority Data
Mar. 28, 2023 (CN) 202310314050.6

(51) Int. Cl. H10W 42/20; H10W 90/00

(52) U.S. Cl. CPC H10W 42/261; H10W 42/281; H10W 90/7295; H10W 90/736

(57) ABSTRACT

The present disclosure provides a fan-out chip packaging structure based on a shielded metal carrier plate and a method, the method comprising: providing a shielded metal carrier plate; forming one or more recesses on a first surface of the shielded metal carrier plate, wherein the recesses extend toward a second surface of the shielded metal carrier plate; applying conductive adhesive to areas on bottom walls of recesses reserved for chips to be fixed, placing the chips, and then baking to strengthen adhesion thereby attaching the chips within the recesses; covering areas of the recesses not occupied by the chips with a filler layer to fill and level the recesses; forming a rewiring layer on the first surface of the shielded metal carrier plate and covering the recesses, wherein the rewiring layer is electrically connected to the chips to enable electrical lead-out of the chips; and forming metal bumps on the rewiring layer.

### FIELD OF TECHNOLOGY

The present disclosure relates to fan-out wafer level packaging technologies, in particular, to a fan-out chip packaging structure based on a shielded metal carrier plate and method for manufacturing the same.

### BACKGROUND

With the continuous progress of microelectronics technology, the feature size of integrated circuits continues to shrink, the interconnection density continues to increase, the requirements for the size of packaging bodies are also becoming more and more stringent, and achieving high-density integration of a variety of different chips packaged in a module as small as possible is undoubtedly a major direction in the current trend of miniaturization in the field of chip packaging. At present, the industry's mainstream is fan-out wafer level packaging technology, which is an embedded packaging technique that achieves fan-out packaging at the wafer level. It is also one of the advanced packaging processes with a high number of I/Os and good integration flexibility, capable of integrating multiple chips vertically and horizontally within a single package.

Existing fan-out chip packaging structures are mostly embedded with silicon carrier boards for multi-chip embedding, and the formation of chip-embedded cavity structures requires expensive and complex processes, and is prone to chip breakage; in addition, when achieving the electromagnetic shielding function of the product by forming a metal layer within the cavity structure, the process is complicated, the material is expensive and the uniform performance of the metal layer cannot be guaranteed; finally, the adoption of adhesive backing films significantly affects the heat dissipation performance of the chips.

### SUMMARY

In view of the above-described shortcomings, the present disclosure provides a fan-out chip packaging structure based on a shielded metal carrier plate and method for manufacturing the same, which is used to solve the problems of high cost, complicated process, poor electromagnetic shielding function and poor heat dissipation performance of the fan-out chip packaging structure in related technologies.

The present disclosure provides a method for manufacturing a fan-out chip packaging structure based on a shielded metal carrier plate, which includes:
providing a shielded metal carrier plate, wherein the shielded metal carrier plate includes a first surface and a second surface opposite to the first surface;
forming one or more recesses on the first surface of the shielded metal carrier plate, wherein the recesses extend toward the second surface of the shielded metal carrier plate;
applying conductive adhesive to areas on bottom walls of recesses reserved for chips to be fixed, placing the chips, and then baking to strengthen adhesion thereby attaching the chips within the recesses;
covering areas of the recesses not occupied by the chips with a filler layer to fill and level the recesses;
forming a rewiring layer on the first surface of the shielded metal carrier plate and covering the recesses, wherein the rewiring layer is electrically connected to the chips to enable electrical lead-out of the chips;
forming metal bumps on the rewiring layer.

Optionally, the material of the shielded metal carrier plate is Kovar alloy, copper or aluminum.

Optionally, the recesses are formed by mechanical processing or wet etching.

Furthermore, the mechanical processing is laser etching.

The present disclosure also provides a fan-out chip packaging structure based on a shielded metal carrier plate, which can be prepared using any of the aforementioned methods, wherein the fan-out chip packaging structure includes:
the shielded metal carrier plate, comprising a first surface and a second surface opposite to the first surface, wherein the first surface has one or more recesses for chip accommodation;
one or more chips, wherein each of the recesses accommodates at least one of the chips, wherein the at least one of the chips is adhered to a bottom surface of the corresponding recess with conductive adhesive;
wherein a first gap exists between each chip accommodated in said recess and a side wall of said recess, wherein the first gap is filled by a filler layer;
a rewiring layer, formed on the first surface of the shielded metal carrier plate and covering the recesses, wherein the rewiring layer is electrically connected to the chips to enable electrical lead-out of the chips; and
metal bumps, formed on the rewiring layer.

Optionally, the rewiring layer comprises a patterned dielectric layer and a patterned metal wiring layer.

Optionally, wherein at least two of the chips are accommodated in each of the recesses, and there is a second gap between two adjacent chips in each of the recesses, and the second gap is filled by the filler layer.

Optionally, the material of the shielded metal carrier plate is Kovar alloy, copper or aluminum.

Optionally, the conductive adhesive is one of conductive silver paste, conductive Die Attach Film (DAF) and solder.

Optionally, each of the recesses comprises one or more chip positions, and each subset of the chips with a same chip position within the different recesses are identical.

As described above, the fan-out chip packaging structure based on a shielded metal carrier plate and the method for manufacturing the same of the present disclosure, directly adopts metal as the carrier plate for multi-chip embedding. This metal serves not only as the carrier plate but also as the electromagnetic shielding layer of the packaging structure. Additionally, due to the metal's stable lower thermal expansion coefficient and high strength, its lower thermal expansion coefficient makes it less prone to deformation during subsequent processing, while its high strength reduces the risk of damage during further processing, thereby reducing the risk of product warping and breakage; in addition, the metal carrier plate is directly used as the electromagnetic shielding layer, and its thickness uniformity can be effectively guaranteed, so that the electromagnetic shielding effect of the packaging structure is significantly improved; furthermore, the use of shielded metal carrier plate preparation chip embedded in the recesses can avoid the complex and high cost of photolithography, dry etching and cleaning and other complex processes, and exempt from the preparation of the shielded metal layer of the process, to further reduce the complexity of the process and reduce costs; finally, the chips can be fixed on the shielded metal carrier plate through the conductive adhesive, based on the excellent heat dissipation properties of the conductive adhesive, the present disclosure can effectively improve the heat dissipation of the packaging structure. Therefore, the manufacturing method and packaging structure of the present disclosure effectively reduces the process complexity of the fan-out chip packaging structure, reduces the manufacturing cost and improves the electromagnetic shielding performance of the fan-out chip packaging structure, heat dissipation performance and reduces the risk of product warping and breakage.

### BRIEF DESCRIPTION OF THE DRAWINGS

FIG. 1 is a cross-sectional structural diagram of a fan-out chip packaging structure in an embodiment.

FIG. 2 is a cross-sectional structural diagram of an intermediate structure obtained after providing a shielded metal carrier plate in the method for manufacturing a fan-out chip packaging structure based on a shielded metal carrier plate of the present disclosure.

FIG. 3 is a cross-sectional structural diagram of an intermediate structure obtained after forming a recess in the method for manufacturing a fan-out chip packaging structure based on a shielded metal carrier plate of the present disclosure.

FIG. 4 is a cross-sectional structural diagram of an intermediate structure obtained after a conductive adhesive is provided in the method for manufacturing a fan-out chip packaging structure based on a shielded metal carrier plate of the present disclosure.

FIG. 5 is a cross-sectional structural diagram of an intermediate structure obtained after adhering a chip in the method for manufacturing a fan-out chip packaging structure based on a shielded metal carrier plate of the present disclosure.

FIG. 6 is a cross-sectional structural diagram of an intermediate structure obtained after filling a filler layer in the method for manufacturing a fan-out chip packaging structure based on a shielded metal carrier plate of the present disclosure.

FIG. 7 is a cross-sectional structural diagram of an intermediate structure obtained after forming a rewiring layer and metal bumps in the method for manufacturing a fan-out chip packaging structure based on a shielded metal carrier plate of the present disclosure, wherein each of the recesses has one of the chips adhered thereto.

FIG. 8 is a cross-sectional structural diagram of an intermediate structure obtained after forming a rewiring layer and metal bumps in the preparation method for manufacturing a fan-out chip packaging structure based on a shielded metal carrier board of the present disclosure, wherein each of the recesses has at least two of the chips adhered thereto.

FIG. 9 is a top view of a fan-out chip packaging structure based on the shielded metal carrier plate of the present disclosure, wherein each of the recesses has four of the chips adhered thereto.

FIG. 10 is a top view of a single package body obtained by cutting the fan-out chip packaging structure of FIG. 9.

### REFERENCE NUMERALS

100 Shielded metal carrier plate
101 First surface
102 Second surface
103 recesses
104 Conductive adhesive
105 Chips
106 First Chip
107 Second Chip
108 Third Chip
109 Fourth chip
110 First Gap
111 Second Gap
112 Filler Layer
113 Rewiring layer
114 Patterned dielectric layer
115 Patterned metal wiring layer
116 Metal Bumps
117 Package
201 Silicon Carrier plate
202 Chips
203 Shielded Metal Layer
204 Backing Films
205 Filler Layer

### DETAILED DESCRIPTION

The following describes the implementation of the present disclosure through specific examples, and those skilled in the art can easily understand other advantages and effects of the present disclosure from the content disclosed in this specification. The present disclosure can also be implemented or applied through other different exemplary embodiments. Various modifications or changes can also be made to all details in the specification based on different points of view and applications without departing from the spirit of the present disclosure.

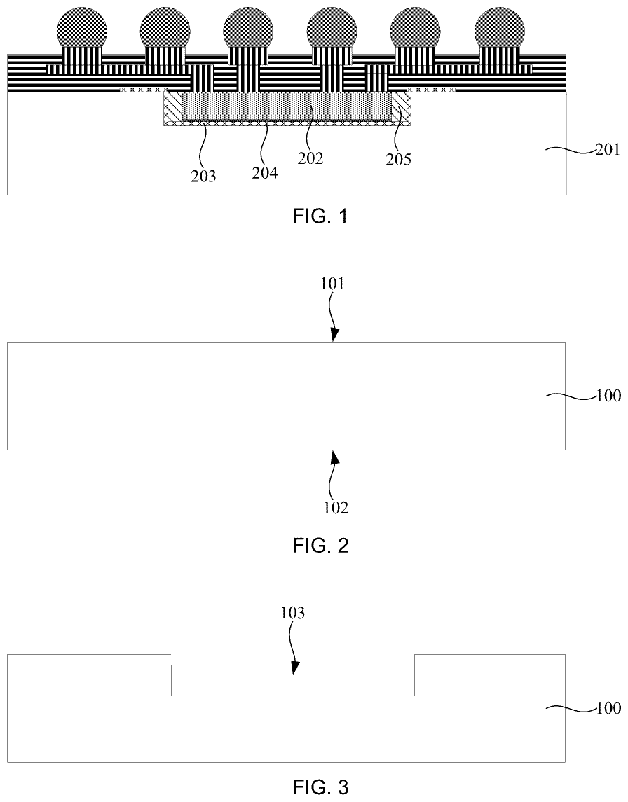

Refer to FIGS. 1-10. It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

FIG. 1 shows a cross-sectional structural diagram of a fan-out chip packaging structure, the packaging structure is mostly a silicon carrier plate 201 for multi-chip embedding, and in forming the cavity structure in which the chips 202 are embedded, it is necessary to complete the process through a complex process such as photolithography, dry etching, cleaning, and so on, which is a complex and costly process, and there is a high risk of the product breaking due to the fragility of silicon in the manufacturing process; additionally, to achieve the electromagnetic shielding function of the product, a shielded metal layer 203 is formed within the cavity structure, the process requires the application of expensive photolithography, physical vapor deposition equipment, electroplating equipment, photoresist removal, corrosion and a series of expensive machines and materials, and the thickness uniformity of the shielded metal layer 203 on side walls of the cavity structure cannot be guaranteed, which affects the electromagnetic shielding effect of the packaging structure and reduces reliability; furthermore, the bonding process of the chips 202 requires the adhesive backing films 204 to be affixed in advance before the chip cutting, while the backing films 204 are expensive and also significantly impair the heat dissipation performance of the chips.

In light of this, the present disclosure provides a method for preparing a fan-out chip packaging structure based on a shielded metal carrier plate, including:
S1: providing a shielded metal carrier plate, wherein the shielded metal carrier plate includes a first surface and a second surface opposite to the first surface;
S2: forming one or more recesses on the first surface of the shielded metal carrier plate, wherein the recesses extend toward the second surface of the shielded metal carrier plate;
S3: applying conductive adhesive to areas on bottom walls of recesses reserved for chips to be fixed, placing the chips, and then baking to strengthen adhesion thereby attaching the chips within the recesses;
S4: covering areas of the recesses not occupied by the chips with a filler layer to fill and level the recesses;
S5: forming a rewiring layer on the first surface of the shielded metal carrier plate and covering the recesses, wherein the rewiring layer is electrically connected to the chips to enable electrical lead-out of the chips;
S6: forming metal bumps on the rewiring layer;

The method for manufacturing the fan-out chip packaging structure of the present disclosure, directly adopts metal as the carrier plate for multi-chip embedding. This metal serves not only as the carrier plate but also as the electromagnetic shielding layer of the packaging structure. Additionally, the metal has a stable lower thermal expansion coefficient and a high strength; its lower thermal expansion coefficient makes it less prone to deformation during subsequent processing, while its high strength reduces the risk of damage during further processing, thereby reducing the risk of product warping and breakage; in addition, the metal carrier plate is directly used as the electromagnetic shielding layer, and its thickness uniformity can be effectively guaranteed, so that the electromagnetic shielding effect of the packaging structure is significantly improved; furthermore, the use of shielded metal carrier plate preparation chip embedded in the recesses can avoid the complex and high cost of photolithography, dry etching and cleaning and other complex processes, and exempt from the preparation of the shielded metal layer of the process, to further reduce the complexity of the process and reduce costs; finally, the chips can be fixed on the shielded metal carrier plate through the conductive adhesive, based on the excellent heat dissipation properties of the conductive adhesive, the present disclosure can effectively improve the heat dissipation of the packaging structure. Therefore, the preparation method of this embodiment effectively reduces the process complexity of the fan-out chip packaging structure, reduces the manufacturing cost and improves the electromagnetic shielding performance of the fan-out chip packaging structure, heat dissipation performance, and reduces the risk of product warping and breakage.

The preparation method of the fan-out chip packaging structure based on a shielded metal carrier board of the present disclosure is described in detail below with reference to the specific figures.

As shown in FIG. 2, first, step S1 includes providing a shielded metal carrier plate 100, wherein the shielded metal carrier plate 100 has a first surface 101 and a second surface 102 opposite to the first surface.

It should be noted here that the first surface 101 and the second surface 102 indicate that the shielded metal carrier plate 100 has opposing sides, simply based on the fact that if one of the sides is defined as a first surface, the opposite side is a second surface, and that the terms “first” and “second” do not have any other particular significance.

As an example, the material of the shielded metal carrier plate 100 is selected to be one with a lower coefficient of expansion, higher strength and better electrical conductivity, such as Kovar alloy, copper or aluminum, and in this embodiment, the material of the shielded metal carrier plate 100 is preferably Kovar alloy, which has an excellent electrical conductivity and a stable lower coefficient of thermal expansion and strength, making it the optimal choice of metal material for the present disclosure.

As shown in FIG. 3, step S2 includes forming one or more recesses 103 on the first surface 101 of the shielded metal carrier plate 100, wherein the recesses 103 extend toward the second surface 102 of the shielded metal carrier plate 100.

The depth, size and number of the recesses 103 are set according to the actual packaging requirements and are not excessively limited herein.

As a preferred example, the recesses 103 are formed by mechanical processing or wet etching, the adoption of which can eliminate the need for the existing complex process of forming recesses using photolithography, dry etching and cleaning, simplify the process complexity, reduce the manufacturing cost, and improve the efficiency. It is preferred to adopt laser etching to form the recesses 103.

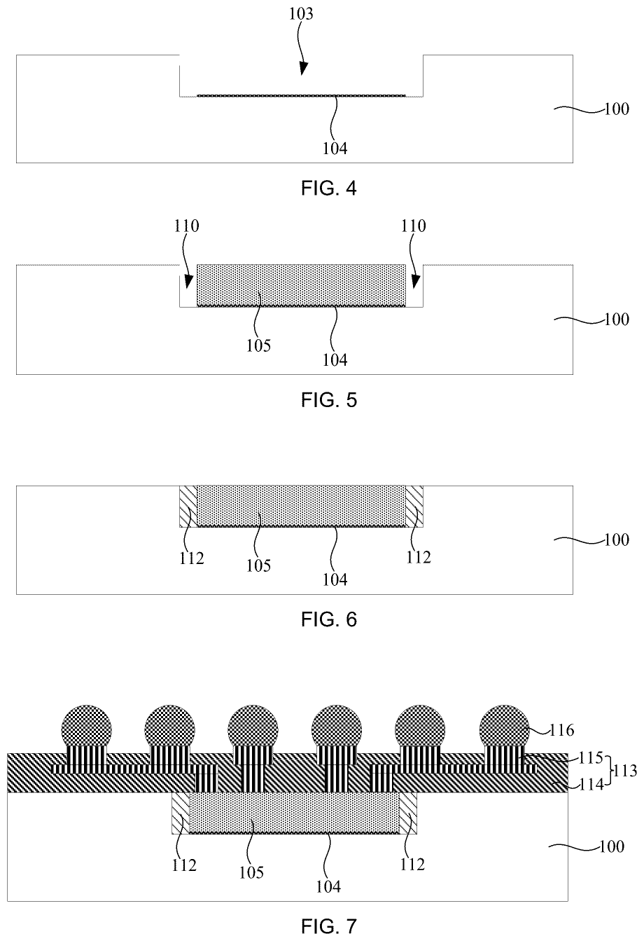

As shown in FIG. 4 and FIG. 5, step S3 includes applying conductive adhesive 104 to areas on bottom walls of recesses 103 reserved for chips to be fixed, as shown in FIG. 4, placing the chips 105, and then baking to strengthen adhesion thereby attaching the chips 105 within the recesses 103, as shown in FIG. 5.

The presently disclosed method for manufacturing the fan-out chip packaging structure based on the shielded metal carrier board can achieve single-chip packaging as well as multiple-chip packaging. For single-chip packaging, each of the recesses 103 has one of the chips 105 adhered thereto; for multiple-chip packaging, each of the recesses 103 has at least two of the chips 105 adhered thereto, and the layout of the at least two chips 105 in said recess 103 is set according to the actual needs.

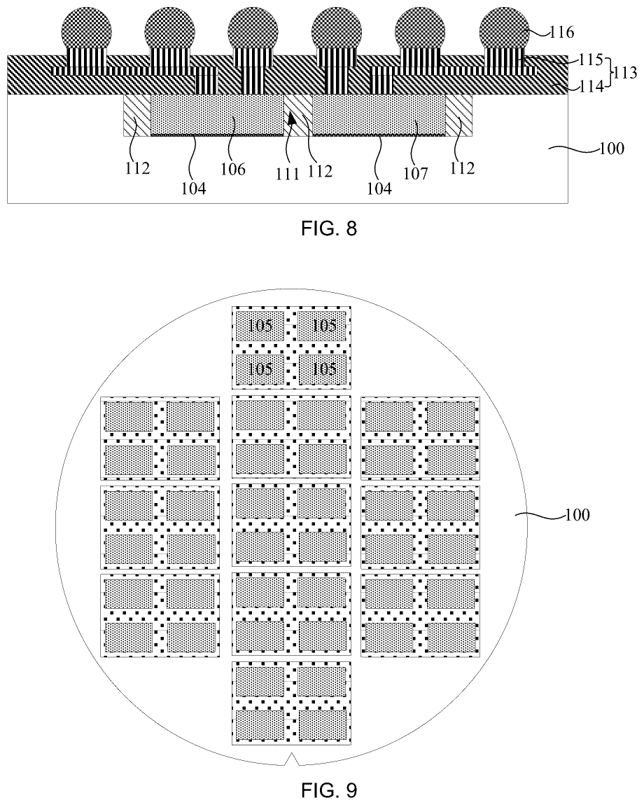

As shown in FIG. 5, there is a first gap 110 between each of the chips 105 adhered in a respective recess 103 and a side wall of said recess 103, and furthermore, as shown in FIG. 8, when multiple chips 105 are adhered in each of the recesses 103, there is a second gap 111 between two adjacent chips 105 in each of the recesses 103.

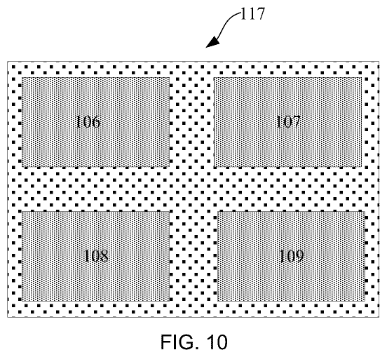

As an example, all of the recesses 103 in the shielded metal carrier plate 100 are identical in shape, and different recesses 103 have the same combination of chips 105 packaged therein. For example, as shown in FIG. 9, four chips A B C D of the chips 105 are packaged in each of the recesses 103, and chips 105 packaged in different recesses 103 are of the same combination (i.e., A+B+C+D), and chips 105 in a same position across different recesses 103 are of the same type, or in other words, chips 105 of the same type are provided in the corresponding positions of different recesses 103. For example, Chip A1 is in Position 1 of Recess 1, Chip B1 is in Position 2 of Recess 1, Chip C1 is in Position 3 of Recess 1, Chip D1 is in Position 4 of Recess 1, Chip A2 is in Position 1 of Recess 2, Chip B2 is in Position 2 of Recess 2, Chip C2 is in Position 3 of Recess 2, Chip D2 is in Position 4 of Recess 2; Chip X1 and Chip X2 are of the same type X, X being A, B, C, or D; Position n in Recess 1 corresponds to Position n in Recess 2. And these four chips 105 in each recess can be of the same or different types; that is, each two of the four types A, B, C, and D can be the same or different; as shown in FIG. 10, the four chips are the first chip 106, the second chip 107, the third chip 108 and the fourth chip 109.

As an example, the chips 105 can be any existing semiconductor chips suitable for packaging, either stand-alone functional chips such as memory chips, circuit chips, etc., or integrated functional chips such as Accelerated Processing Unit (APU) chips, Graphics Processing Unit (GPU) chips, etc.

As an example, the conductive adhesive 104 may be one of conductive silver paste, conductive Die Attach Film (DAF) and solder.

As shown in FIG. 6, step S4 includes covering areas of the recesses 103 not occupied by the chips 105 with a filler layer 112 to fill and level the recesses 103, thus making the first surface 101 of the shielded metal carrier board 100 flat, facilitating the subsequent preparation of a rewiring layer.

As an example, a vacuum underfill process is used to fill and level the recesses 103. When at least two of the chips 105 are adhered in each of the recesses 103, the first gap 110 and the second gap 111, as described above, are filled simultaneously with the filling layer 112 using the vacuum underfill process.

As shown in FIG. 7 and FIG. 8, step S5 includes forming a rewiring layer 113 on the first surface 101 of the shielded metal carrier plate 100 and on the surface of the recesses 103, wherein the rewiring layer 113 is electrically connected to the chips 105 to enable electrical lead-out of the chips. As in FIG. 7, each of the recesses 103 has at least one of the chips 105 adhered thereto, and the rewiring layer 113 is electrically connected to said chip, and as in FIG. 8, there are two chips, a first chip 106 and a second chip 107, adhered in each of the recesses 103, and the rewiring layer 113 is electrically connected to each of said two chips.

As an example, the rewiring layer 113 includes a patterned dielectric layer 114 and a patterned metal wiring layer 115. The method of forming the rewiring layer 113 includes: forming a dielectric layer on the first surface 101 of the shielded metal carrier plate 100 and etching the dielectric layer using conventional photolithographic, thereby etching to form the patterned dielectric layer 114; forming a metal wiring layer on the patterned dielectric layer 114 and the bare first surface 101 of the shielded metal carrier plate 100, and patterning it to form the patterned metal wiring layer 115. It should be noted here that according to practical needs, the rewiring layer 113 may be a plurality of layers, each of which is prepared in the same way as the rewiring layer 113, and all of which may be prepared by the method described above.

As shown in FIG. 7 and FIG. 8, step S6 includes forming metal bumps 116 on the rewiring layer 113;

As an example, the metal bumps 116 include one of a gold-tin solder ball, a silver-tin solder ball, a copper-tin solder ball; alternatively, the metal bumps 116 include metal posts, and solder balls formed on the metal posts, and, preferably, the metal posts are copper posts or nickel posts. In this embodiment, the metal bumps 116 are gold-tin solder balls, the step of making which includes first forming a gold-tin layer on the surface of the rewiring layer 113, and then adopting a high temperature reflow process to make the gold-tin layer reflow into a ball shape, and forming gold-tin solder balls after cooling down; alternatively, a ball-planting process is employed to form gold-tin solder balls.

As an example, as shown in FIG. 9, a fan-out chip packaging structure is formed on the shielded metal carrier plate 100, and is subsequently cut to obtain single package bodies 117 as in FIG. 10.

As shown in FIG. 7 to FIG. 10, the present disclosure also provides a fan-out chip packaging structure based on a shielded metal carrier plate, and the fan-out chip packaging structure based on the shielded metal carrier plate can be manufactured using the method described above. For the beneficial effects achieved by the fan-out chip packaging structure, please refer to the method described above; the fan-out chip packaging structure includes:
the shielded metal carrier plate 100, wherein the shielded metal carrier plate 100 includes a first surface 101 and a second surface 102 opposite to the first surface, wherein the first surface 101 has one or more recesses 103 for chip accommodation;
one or more chips 105, wherein each of the recesses 103 accommodates at least one of the chips 105, wherein the at least one of the chips 105 is adhered to a bottom surface of the corresponding recess 103 with conductive adhesive 104;
wherein a first gap 110 exists between each of chips 105 accommodated in the recesses 103 and a sidewall of the recesses 103, wherein the first gap 110 is filled by a filler layer 112;
a rewiring layer 113, formed on the first surface 101 of the shielded metal carrier plate 100 and covering the recess 103, the rewiring layer 113 is electrically connected to the chips 105 to enable electrical lead-out of chips;
metal bumps 116, formed on the rewiring layer 113.

As an example, the material of the shielded metal carrier plate 100 is one with a lower coefficient of expansion, higher strength and better electrical conductivity, such as Kovar alloy, copper or aluminum; in one embodiment, the material of the shielded metal carrier plate 100 is preferably Kovar alloy, which has excellent electrical conductivity attributes and a stable and low coefficient of thermal expansion and strength, making it the optimal choice of metal material for this embodiment.

The fan-out chip packaging structure based on the shielded metal carrier plate of the present disclosure may be used to achieve single-chip packaging as well as multiple-chip packaging. For single-chip packaging, each of the recesses 103 has one of the chips 105 adhered thereto; for multiple-chips, each of the recesses 103 has at least two of the chips 105 adhered thereto, and the layout of the at least two chips 105 in said recess 103 is set according to the actual needs.

As shown in FIG. 5, there is a first gap 110 between each of the chips 105 adhered in a respective recess 103 and a side wall of said recess 103, and furthermore, as shown in FIG. 8, when multiple chips 105 are adhered in each of the recesses 103, there is a second gap 111 between two adjacent chips 105 in each of the recesses 103, and the second gap 111 is also filled by the filling layer 112.

As an example, all of the recesses 103 in the shielded metal carrier plate 100 are identical in shape, and different recesses 103 have the same combination of chips 105 packaged therein. For example, as shown in FIG. 9, four chips A B C D of the chips 105 packaged in each of the recesses 103, and chips 105 packaged in different recesses 103 are of the same combination (i.e., A+B+C+D), and chips 105 in a same position across different recesses 103 are of the same type, or in other words, chips 105 of the same type are provided in the corresponding positions of different recesses 103. For example, Chip A1 is in Position 1 of Recess 1, Chip B1 is in Position 2 of Recess 1, Chip C1 is in Position 3 of Recess 1, Chip D1 is in Position 4 of Recess 1, Chip A2 is in Position 1 of Recess 2, Chip B2 is in Position 2 of Recess 2, Chip C2 is in Position 3 of Recess 2, Chip D2 is in Position 4 of Recess 2; Chip X1 and Chip X2 are of the same type X, X being A, B, C, or D; Position n in Recess 1 corresponds to Position n in Recess 2. And these four chips 105 in each recess can be of the same or different types; that is, each two of the four types A, B, C, and D can be the same or different; as shown in FIG. 10, the four chips are the first chip 106, the second chip 107, the third chip 108 and the fourth chip 109.

As an example, the chips 105 can be any existing semiconductor chips suitable for packaging, either stand-alone functional chips such as memory chips, circuit chips, etc., or integrated functional chips such as Accelerated Processing Unit (APU) chips, Graphics Processing Unit (GPU) chips, etc.

As an example, the rewiring layer 113 includes a patterned dielectric layer 114 and a patterned metal wiring layer 115.

As an example, the conductive adhesive 104 may be one of conductive silver paste, conductive Die Attach Film (DAF) and solder.

In summary, the present disclosure provides a fan-out chip packaging structure based on a shielded metal carrier plate and method for manufacturing the same, which directly adopts metal as a carrier plate for multi-chip embedding, with the metal acting as a carrier plate and at the same time as an electromagnetic shielded metal layer of the packaging structure; the metal has a stable and lower coefficient of thermal expansion and a high strength, the lower coefficient of thermal expansion makes it not easy to be deformed during the subsequent processing, and the high strength makes it less likely to be damaged during subsequent processes, reducing the risk of product warping and breakage; in addition, the metal carrier plate is directly used as the electromagnetic shielding layer, and its thickness uniformity can be effectively guaranteed, so that the electromagnetic shielding effect of the packaging structure is significantly improved; furthermore, using a shielded metal carrier plate to prepare the recesses for chip embedding eliminates the need for complex and costly process such as photolithography, dry etching and cleaning, as well as these processes of prepare shielded metal layers, to further reduce process complexity and costs; finally, the chips can be fixed on the shielded metal carrier plate through the conductive adhesive, and based on the excellent heat dissipation properties of the conductive adhesive, the present disclosure can effectively improve the heat dissipation of the packaging structure. Therefore, the preparation method and packaging structure of the present disclosure effectively reduces the process complexity of the fan-out chip packaging structure, reduces the manufacturing cost and improves the electromagnetic shielding performance of the fan-out chip packaging structure, heat dissipation performance and reduces the risk of product warping and breakage. Therefore, the present disclosure effectively overcomes various shortcomings in the existing technology and has high industrial utilization value.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A fan-out chip packaging structure based on a shielded metal carrier plate, comprising:
the shielded metal carrier plate, comprising a first surface and a second surface opposite to the first surface, wherein the first surface has one or more recesses for chip accommodation;
one or more chips, wherein each of the recesses accommodates at least one of the chips, wherein the at least one of the chips is adhered to a bottom surface of the corresponding recess with conductive adhesive;
wherein a first gap exists between each chip accommodated in said recess and a side wall of said recess, wherein the first gap is filled by a filler layer;
a rewiring layer, formed on the first surface of the shielded metal carrier plate and covering the recesses, wherein the rewiring layer is electrically connected to the chips to enable electrical lead-out of the chips; and
metal bumps, formed on the rewiring layer.

2. The fan-out chip packaging structure based on the shielded metal carrier board according to claim 1, wherein the rewiring layer comprises a patterned dielectric layer and a patterned metal wiring layer.

3. The fan-out chip packaging structure based on the shielded metal carrier board according to claim 1, wherein at least two of the chips are accommodated in each of the recesses, and there is a second gap between two adjacent chips in each of the recesses, and the second gap is filled by the filler layer.

4. The fan-out chip packaging structure based on the shielded metal carrier plate according to claim 1, wherein a material of the shielded metal carrier plate is Kovar alloy, copper or aluminum.

5. The fan-out chip packaging structure based on the shielded metal carrier plate according to claim 1, wherein the conductive adhesive is one of conductive silver paste, conductive Die Attach Film (DAF) and solder.

6. The fan-out chip packaging structure based on the shielded metal carrier plate according to claim 1, wherein each of the recesses comprises one or more chip positions, and each subset of the chips with a same chip position within the different recesses are identical.

7. A method for manufacturing a fan-out chip packaging structure based on a shielded metal carrier plate, comprising:
providing a shielded metal carrier plate, wherein the shielded metal carrier plate comprises a first surface and a second surface opposite to the first surface;
forming one or more recesses on the first surface of the shielded metal carrier plate, wherein the recesses extend toward the second surface of the shielded metal carrier plate;
applying conductive adhesive to areas on bottom walls of recesses reserved for chips to be fixed, placing the chips, and then baking to strengthen adhesion thereby attaching the chips within the recesses.
covering areas of the recesses not occupied by the chips with a filler layer to fill and level the recesses;
forming a rewiring layer on the first surface of the shielded metal carrier plate and covering the recesses, wherein the rewiring layer is electrically connected to the chips to enable electrical lead-out of the chips;
forming metal bumps on the rewiring layer.

8. The method for manufacturing the fan-out chip packaging structure based on the shielded metal carrier plate according to claim 7, wherein the material of the shielded metal carrier plate is Kovar alloy, copper or aluminum.

9. The method for manufacturing the fan-out chip packaging structure based on the shielded metal carrier plate according to claim 7, wherein the recesses are formed by mechanical processing or wet etching.

10. The method for manufacturing the fan-out chip packaging structure based on the shielded metal carrier plate according to claim 9, wherein the mechanical processing is laser etching.
